(19) United States
(12) Patent Application Publication
(10) Pub. No.: US 2008/0160724 A1
(43) Pub. Date: Jul. 3, 2008

(54) METHOD OF DICING

(75) Inventors: Hyun-Jung SONG, Gyeonggi-do (KR); Hak-Kyoon BYUN, Chungcheongnam-do (KR); Jong-Bo SHIM, Chungcheongnam-do (KR); Min-Ok NA, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/945,896

(22) Filed: Nov. 27, 2007

(30) Foreign Application Priority Data
Dec. 29, 2006 (KR) 2006-0138769

(51) Int. Cl. H01L 21/304

(52) U.S. Cl. 438/462; 257/E21.238

(57) ABSTRACT

Provided is a method of dicing a wafer where a plurality of semiconductor device regions is formed on a front side of the wafer, the semiconductor device regions being separated by scribe lanes, the method comprising dicing the wafer by irradiating a laser beam on a backside of the wafer along the scribe lanes. A laser beam is irradiated from an opposite side of the semiconductor device regions of the wafer so that thermal influence on the semiconductor device regions is minimized to improve the strength of a semiconductor chip. Furthermore, a third tape is used to maintain an arrangement of the semiconductor chips so as to minimize adherence problems caused by the laser beam.

### CROSS-REFERENCE TO RELATED PATENT APPLICATION

This application claims priority under 35 USC §119 to Korean Patent Application No. 10-2006-0138769, filed on Dec. 29, 2006 in the Korean Intellectual Property Office, the contents of which are incorporated herein in their entirety by reference.

### BACKGROUND

1. Technical Field

The present invention relates to a method of dicing a wafer, and more particularly, to a method of dicing a wafer that can reduce or minimize the reduction of chip strength due to dicing and reduce dicing related problems, such as pick-up errors, that may occur in subsequent packaging processes.

2. Description of the Related Art

A dicing process is implemented in order to divide a plurality of semiconductor device regions formed on a wafer into individual semiconductor chips. A sawing blade made of diamond or alloyed hard metal has been conventionally used in the dicing process.

However, the interval between semiconductor device regions has been narrowed to increase the number of semiconductor chips which can be obtained from one wafer. As a result, the width of scribe lanes which a sawing blade passes over has also been significantly reduced. Since the width of the scribe lanes has been reduced to the point of being close to the thickness of the sawing blade in recent years, a process margin is too narrow to dice a wafer using the sawing blade.

The thickness of the semiconductor chip is also required to be further decreased to accommodate demand for lighter, thinner, shorter and increasingly miniaturized semiconductor chips. When the thickness of the wafer on which chips are formed is reduced to produce thinner semiconductor chips, the semiconductor chips can be easily damaged by a sawing blade in a dicing process.

Accordingly, a dicing method using a laser was previously proposed and is currently used in some cases. Since a laser can dice a thinner wafer with narrower scribe lanes without chipping as compared to the sawing blade, the laser has been mostly used as an alternative dicing method to the sawing blade approach.

However, the laser dicing method also has some room for improvement,

FIG. 1 is a schematic view illustrating a mechanism for laser dicing. FIG. 2 is a cross-sectional view illustrating a heat-affected zone (HAZ) from a laser dicing method.

Referring to FIG. 1, a laser beam with a wavelength and power which can react with silicon (Si) is focused on a wafer to dissociate a silicon bond. As a result, a melt pool is formed around the point where the laser beam is focused, particularly at the center of the point, a key-hole being formed due to sublimation of the dissolved silicon. Furthermore, a heat-affected zone (HAZ) is formed around the melt pool as a result of conduction of heat generated by the laser beam. While the laser beam is irradiated along the scribe lanes, the above phenomena occur so that the silicon wafer is fully or partially cut.

Referring to FIG. 2, looking at the section of a laser-diced substrate, an HAZ having the same shape as that shown in FIG. 2 may be observed in the section of the substrate. Specifically, closer to the surface of the wafer where the laser beam is irradiated, the melted width, as well as the degree of property change affected by the HAZ, increases. Therefore, the conventional dicing method using the laser beam for cutting a wafer on which a semiconductor device is formed has a problem in that it causes significant damage to the semiconductor device as well as reducing the chip strength.

A die-attach film (DAF) is generally attached to the bottom of a wafer for process automation to prevent individual semiconductor chips from being scattered after the dicing process, which may cause a problem in a laser sawing process. While a laser beam is irradiated to cut a wafer, an adhesive layer used to attach the DAF to the wafer is also melted and may stick to a base film of the DAF due to an undesired secondary bonding.

FIG. 3 is a cross-sectional view illustrating an adherence phenomenon that may occur between a die-attach film (DAF) and a wafer due to a laser dicing method. FIG. 4 is a micro-photographic image of a region where an adherence phenomenon occurs.

FIG. 3 is a schematic view for explaining the undesired secondary bonding. A wafer 10 is attached onto a DAF 20 including an adhesive layer 22 and a base film 24. The wafer 10 is separated into individual semiconductor devices by a laser dicing method. However, secondary bonding between the adhesive layer 22 and the base film 24 occurs in portions (A) as can be seen in the enlarged section of FIG. 3. That is, the adhesive layer 22 is stuck to the base film 24 by the secondary bonding (as shown in FIG. 4).

This adherence phenomenon may cause a pick-up error when packaging the individual semiconductor chips, thereby reducing manufacturing yield rate and product quality. Accordingly, what is needed is a laser dicing method that can reduce damage to semiconductor chips during dicing and minimize pick-up errors in subsequent packaging steps.

### SUMMARY

The present invention provides a method of dicing a wafer that minimizes strength degradation of semiconductor chips due to the dicing process. The present invention also provides a method of dicing a wafer that minimizes strength degradation of the chips and minimizes problems, such as a pick-up error, which can occur in subsequent packaging processes.

According to an aspect of the present invention, there is provided a method of dicing a wafer including a plurality of semiconductor device regions formed on a front side and separated by scribe lanes, the method including dicing the wafer by irradiating a laser beam to a backside of the wafer along the scribe lanes.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a mechanism of a laser dicing method;

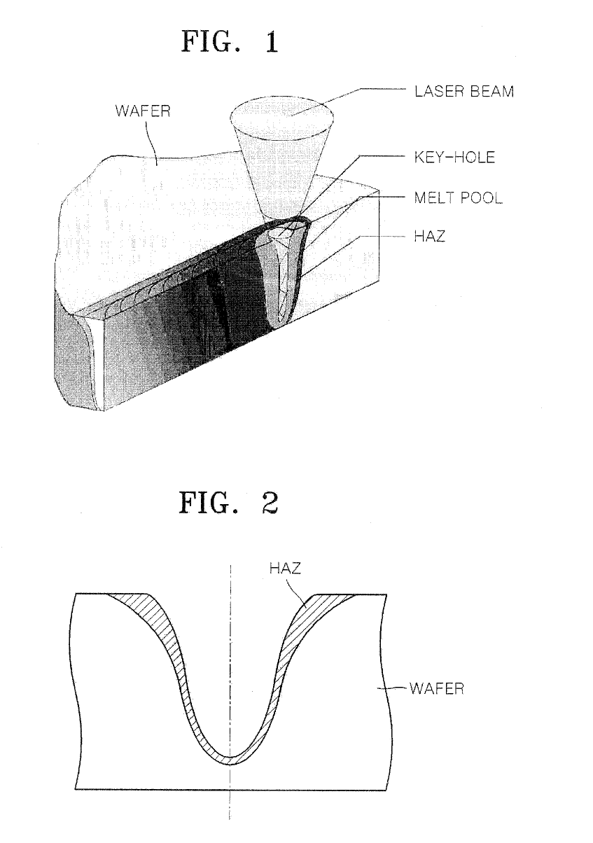

FIG. 2 is a cross-sectional view illustrating a heat-affected zone (HAZ) from a laser dicing method;

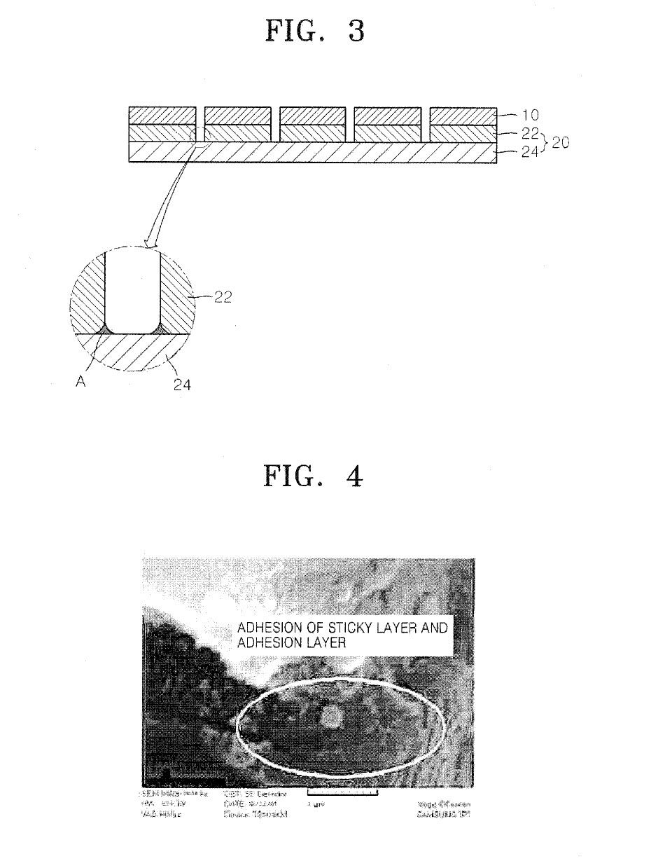

FIG. 3 is a cross-sectional view illustrating an adherence phenomenon that may occur between a die-attach film (DAF) and a wafer due to a laser dicing method;

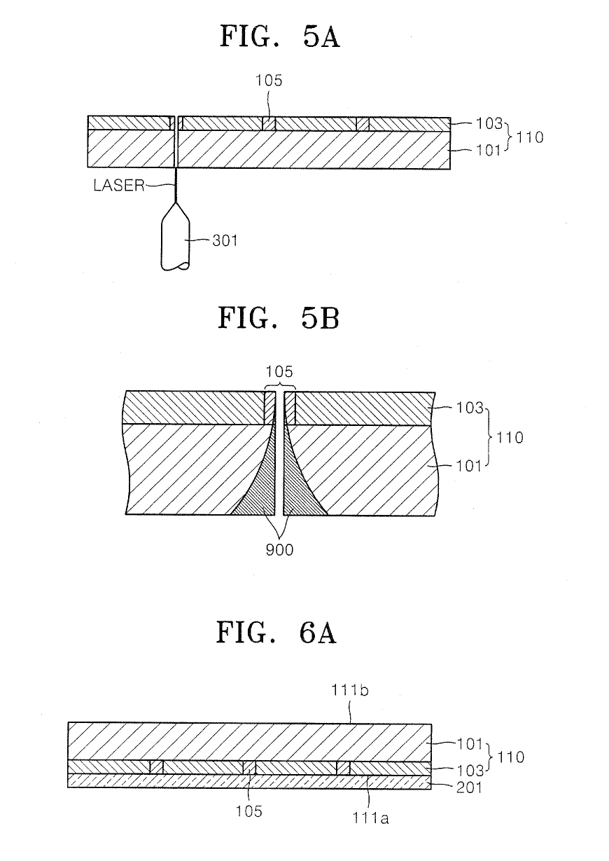

FIG. 4 is a micro-photographic image of a region where an adherence phenomenon occurs;

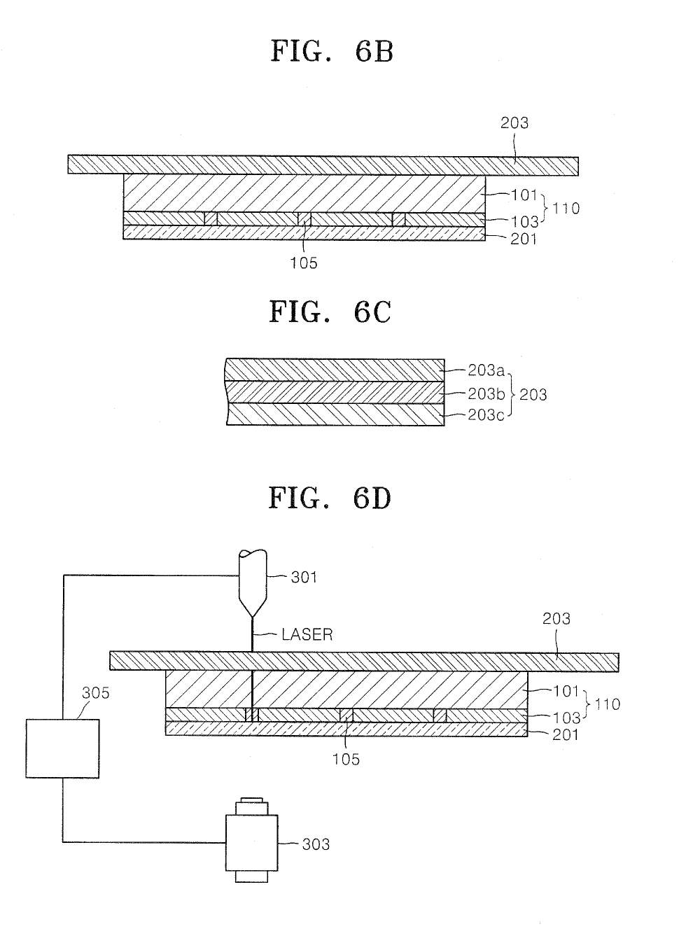

FIGS. 5A and 5B are schematic views illustrating a semiconductor device region that is minimally affected by heat in a dicing method according to an embodiment of the present invention;

FIGS. 6A through 6H are side sectional views schematically illustrating a dicing method according to another embodiment of the present invention; and

FIGS. 7A to 7C are side sectional views schematically illustrating an optional phased dicing operation that can be included in a dicing method according to an embodiment of the present invention.

### DETAILED DESCRIPTION

The present invention will be described more fully hereinafter with reference to the accompanying drawings in which preferred embodiments of the invention are shown. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the forms of elements are exaggerated for clarity. To facilitate understanding, identical reference numerals have been used, where possible, to designate identical elements that are common to the figures.

Furthermore, various elements and regions in the drawings are schematically illustrated. Accordingly, it should be understood that the present invention is not limited to relative sizes or intervals illustrated in the drawings. When written in this description that one layer is disposed on another layer or semiconductor chip, the former layer may be either directly in contact with the other layer or semiconductor chip, or may have another layer interposed therebetween.

An embodiment according to the present invention provides a method of dicing a wafer by irradiating a laser beam to the backside of a the wafer along the scribe lanes, where a plurality of semiconductor device regions is formed on the front side of the wafer and separated by the scribe lanes.

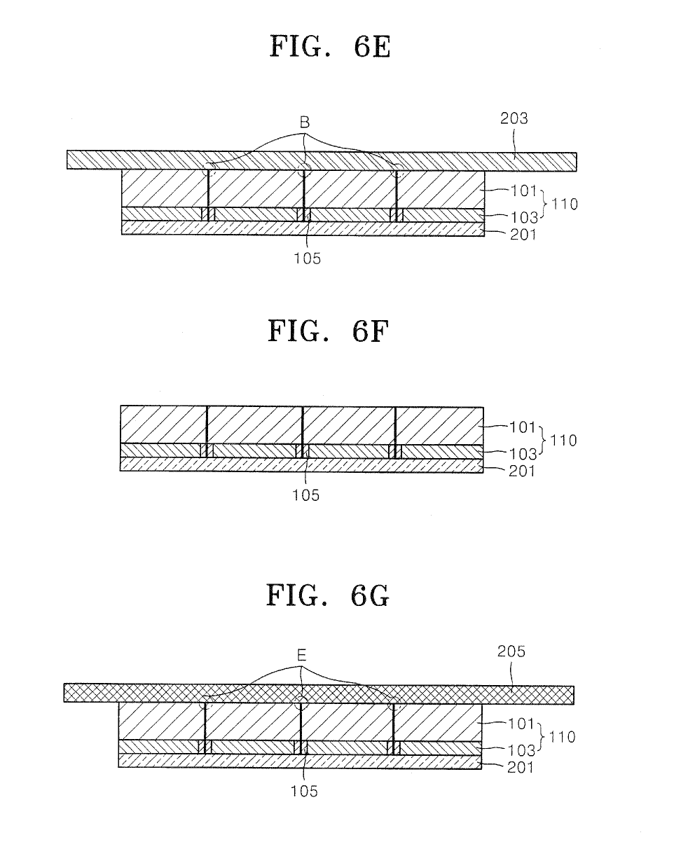

FIGS. 5A and 5B are schematic views illustrating a dicing method according to an embodiment of the present invention and a heat-affected zone (HAZ) from the dicing method.

Referring to FIG. 5A, semiconductor device regions 103 are formed on the front side of a substrate 101. The semiconductor device regions 103 are isolated from one another by scribe lanes 105. A laser irradiator 301 irradiates the backside of the substrate 101 with a laser beam for a dicing process. Although the front side and backside of the substrate 101 can be defined in other ways, herein, the side where the semiconductor device region 103 is formed is defined as a front side, while the opposite side is defined as a backside.

When laser light is irradiated on the backside, an HAZ 900, as shown in FIG. 5B, is formed. Referring to FIG. 5B, the width of the HAZ 900 gradually becomes wider toward the backside of the substrate 101. The reason for this is that heat resulting from the laser beam irradiated to the backside can be transferred from an irradiated point to adjacent regions.

Accordingly, at the front side of the substrate 101, the influence of the HAZ 900 especially on the semiconductor device region 103 is insignificant. Since the influence of the HAZ 900 on the semiconductor device region 103 is insignificant, a reduction of the chip strength is also insignificant. On the other hand, if laser light were downwardly irradiated to the front side, as in a conventional dicing method, the width of the HAZ at the front side would be much wider than the HAZ 900 formed according to the embodiment of the present invention. Accordingly, it can be easily understood that the chip strength will be significantly reduced at the front side when using the conventional method. Conversely, when using the dicing method according to embodiments of the present invention, the chip strength is not significantly reduced by the HAZ.

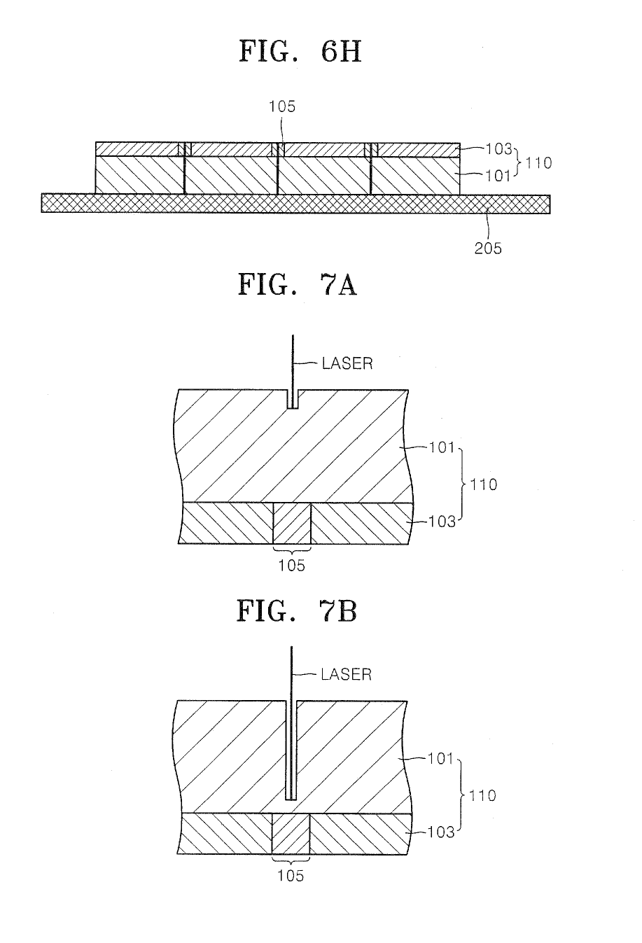

FIGS. 6A through 6H are side cross-sectional views illustrating a dicing method according to another embodiment of the present invention.

Referring to FIG. 6A, semiconductor device regions 103 are formed on the front side of a substrate 101 and are separated from one another by scribe lanes 105. A first tape 203 (shown in FIG. 6B) may be attached to the backside 111b of a wafer 110 including the substrate 101 and the semiconductor device regions 103. A second tape 201 may be attached to the front side 111a of the wafer 110.

According to some embodiments of the present invention, the thickness of the substrate 101 can be appropriately adjusted, for example, by an abrasion method on the backside 111b of the wafer 110. For example, the abrasion method may include, but is not limited to, a grinding method, a spin-etching method, or a polishing method.

Referring to FIG. 6C, according to some embodiments, the first tape 203 may include a base film 203a, a first adhesive layer 203b, and a second adhesive layer 203c. The first adhesive layer 203b may be formed of a material that decreases in adhesive strength when exposed to ultraviolet light. The second adhesive layer 203c may be formed of a material which can be easily adhered to the first adhesive layer 203b and the wafer 110. The base film 203a, the first adhesive layer 203b, and the second adhesive layer 203c, which are included in the first tape 203, can be manufactured using a well-known base film and an adhesive layer material.

As described above, the second tape 201 and the first tape 203 are respectively attached to the front side 111a and the backside 111b of the wafer 110. Here, a dicing process can be performed by irradiating a laser beam to the backside 111b of the wafer 110.

Referring to FIG. 6D, laser light emitted from a laser irradiation device 301 is irradiated on the backside 111b of the wafer 110 along the scribe lanes 105 formed on the front side 111a, so that the wafer 110 can be diced. Specifically, the laser light is irradiated on the backside 111b of the wafer 110 in regions corresponding to the scribes lanes 105 formed on the front side 111a of the wafer 110. According to some embodiments, for the purpose of determining an irradiation position, the laser irradiation device 301 can include a visualization device 303 for recognizing the location of the scribe lane 105, and a control and driving device 305 for controlling the irradiation position of the laser irradiation device 301 based on the location recognized by the visualization device 303.

The second tape 201 may be optically transparent so that the visualization device 303 can recognize the location of the scribe lane 105.

When the laser beam is irradiated along the scribe lanes 105 as shown in FIG. 6D, the wafer 110 will be divided into individual semiconductor device regions 103 as shown in FIG. 6E. However, the laser beam does not cut the base film 203a of the first tape 203, and so the semiconductor device regions 103 will not scatter after the dicing process.

The first adhesive layer 203b of the first tape 203 may be adhered to the base film 203a and/or the second adhesive layer 203c at the points B by the irradiated laser beam depending on the composition of the first adhesive layer 203b. Therefore, if a packaging process were commenced with such an adherence condition, a problem, such as a pick-up error, may arise from the adherence condition, so that an error can occur in the packaging process. Accordingly, a further process to account for the adherence condition can be used prior to the packaging process.

To account for this adherence problem, according to some embodiments, the first tape 203 is replaced with a new third tape 205. Specifically, after the first tape 203 is removed (refer to FIG. 6F), the third tape 205 is attached to the same position previously occupied by the first tape 203 (refer to FIG. 6G). The third tape 205, for example, can be formed of the same material and in the same structure as the first tape 203, but is not specifically limited to this.

Thus, if the third tape 205 is attached after a removal of the first tape 203, the adherence problem at the points B can be resolved. That is, the first adhesive layer 203b, or the first and second adhesive layers 203b and 203c including the base film 203a are removed, so that the adherence problem is resolved. Further, even though the first tape 203 is removed, the second tape 201 still holds the diced semiconductor chips so that the positions of the individual semiconductor chips can be maintained without scattering.

Referring to FIG. 6H, the second tape 201 is removed. Once the second tape 201 is removed, a subsequent packaging process can progress smoothly without problems, such as a pick-up error.

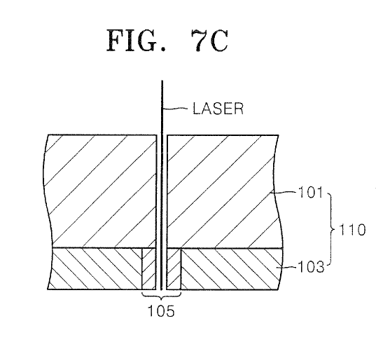

According to some embodiments, when laser light is applied to the water during the dicing process in FIG. 6D, the wafer can be irradiated multiple times with the laser beam such that the wafer is diced step by step. In other words, a single scribe lane 105 may be irradiated multiple times in order to completely separate the two adjacent semiconductor device regions 103, as further described below with reference to FIGS. 7A-7C.

Referring to FIG. 7A, the irradiation conditions of laser light are adjusted so as to cut a wafer only to the extent of a first predetermined depth initially (a first operation). Then, the irradiation conditions of laser light are adjusted so as to cut the wafer to a second predetermined depth, which may be adjacent to the semiconductor device regions 103 (a second operation). Finally, laser light is irradiated along the scribe lanes 105 so that semiconductor device regions 103 can be completely separated from each other (a third operation).

Although the embodiment of FIGS. 7A through 7C illustrates a cutting method including three operation steps, the dicing method may include two, four, or more operations.

A dicing method according to the present invention minimizes strength deterioration of semiconductor chips and thereby reduces problems, such as pick-up errors, that may occur in the packaging process.

According to an aspect of the present invention, there is provided a method of dicing a wafer including a plurality of semiconductor device regions formed on a front side and separated by scribe lanes, the method including dicing the wafer by irradiating a laser beam to a backside of the wafer in regions corresponding to the scribe lanes.

A first tape may be attached to the backside of the wafer. The first tape may include a base film, a first adhesive layer formed on the base film, and a second adhesive layer formed on the first adhesive layer. Here, the second adhesive layer may be attached to the backside of the wafer. The first adhesive layer may decrease in adhesive strength when exposed to ultraviolet light.

A second tape may be formed on a front side of the wafer. The second tape may be optically transparent. The method may further include recognizing the scribe lanes formed on the wafer between the semiconductor device regions by using a visualization device.

The dicing of the wafer may be sequentially performed by irradiating a laser beam two or more times.

According to another aspect of the present invention, there is provided a method of dicing a wafer including a plurality of semiconductor device regions formed on a front side and separated by scribe lanes, a first tape attached to a backside of the wafer, and a second tape attached to the front side of the wafer, the first tape including a base film, a first adhesive layer formed on the base film, and a second adhesive layer formed on the first adhesive layer and attached to the backside of the wafer, the method including: irradiating a laser beam to the backside of the wafer in regions corresponding to the scribe lanes; removing the first tape; attaching a third tape to the backside of the wafer after removing the first tape; and removing the second tape.

According to still another aspect of the present invention, there is provided a method of dicing a wafer comprising: applying a first tape to a front side of the wafer, the front side including semiconductor device regions separated by scribe lanes; applying a second tape to a backside of the wafer; aligning a laser to regions on the backside of the wafer corresponding to the scribe lanes on the front side of the wafer; irradiating a laser beam from the laser onto the backside of the wafer so as to cut through the scribe lanes; removing the first tape; applying a third tape to the front side of the wafer; and removing the second tape.

Aligning the laser may include using a visualization device to identify the scribe lanes on the front side of the wafer. The first tape may include a base film, a first adhesive layer formed on the base film, and a second adhesive layer formed on the first adhesive layer. The first adhesive layer may decrease in adhesive strength when exposed to ultraviolet light. Removing the first tape may comprise exposing the first tape to ultraviolet light. The third tape may be substantially the same as the first tape.

Irradiating the laser beam may comprise irradiating the laser beam onto the wafer at least two times. Each time the laser beam is irradiated onto the wafer a portion of a depth of the wafer may be cut. The second tape may be optically transparent.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of dicing a wafer including a plurality of semiconductor device regions formed on a front side of the wafer, the semiconductor device regions separated by scribe lanes, the method comprising dicing the wafer by irradiating a laser beam on a backside of the wafer in regions corresponding to the scribe lanes.

2. The method of claim 1, further comprising attaching a first tape to the backside of the wafer before irradiating the laser beam, the first tape including a base film, a first adhesive layer formed on the base film, and a second adhesive layer formed on the first adhesive layer and attached to the backside of the wafer.

3. The method of claim 2, wherein the first adhesive layer decreases in adhesive strength when exposed to ultraviolet light.

4. The method of claim 1, wherein a second tape is formed on a front side of the wafer.

5. The method of claim 4, wherein the second tape is optically transparent.

6. The method of claim 5, further comprising aligning the laser beam to the scribe lanes using a visualization device.

7. The method of claim 1, wherein dicing the wafer comprises irradiating the laser beam two or more times.

8. A method of dicing a wafer including a plurality of semiconductor device regions formed on a front side of the wafer, the semiconductor device regions separated by scribe lanes, a first tape attached to a backside of the wafer, and a second tape attached to the front side of the wafer, the first tape including a base film, a first adhesive layer formed on the base film, and a second adhesive layer formed on the first adhesive layer and attached to the backside of the wafer, the method comprising:
irradiating a laser beam on the backside of the wafer in regions corresponding to the scribe lanes;
removing the first tape;
attaching a third tape to the backside of the wafer after removing the first tape; and
removing the second tape.

9. A method of dicing a wafer, the method comprising:
applying a first tape to a front side of the wafer, the front side including semiconductor device regions separated by scribe lanes;
applying a second tape to a backside of the wafer;
aligning a laser to regions on the backside of the wafer corresponding to the scribe lanes on the front side of the wafer;
irradiating a laser beam from the laser onto the backside of the wafer so as to cut through the scribe lanes;
removing the first tape;
applying a third tape to the front side of the wafer; and
removing the second tape.

10. The method of claim 9, wherein aligning the laser includes using a visualization device to identify the scribe lanes on the front side of the wafer.

11. The method of claim 10, wherein the second tape is optically transparent.

12. The method of claim 9, wherein the first tape includes a base film, a first adhesive layer formed on the base film, and a second adhesive layer formed on the first adhesive layer.

13. The method of claim 12, wherein the first adhesive layer decreases in adhesive strength when exposed to ultraviolet light.

14. The method of claim 13, wherein removing the first tape comprises exposing the first tape to ultraviolet light.

15. The method of claim 12, wherein the third tape is substantially the same as the first tape.

16. The method of claim 9, wherein irradiating the laser beam comprises irradiating the laser beam onto the wafer at least two times.

17. The method of claim 16, wherein each time the laser beam is irradiated onto the wafer a portion of a depth of the wafer is cut.
